(19) United States
(12) Patent Application Publication
(10) Pub. No.: US 2019/0062904 A1
(43) Pub. Date: Feb. 28, 2019

(54) INTEGRATED EPITAXY SYSTEM HIGH TEMPERATURE CONTAMINANT REMOVAL

(71) Applicant: Applied Materials, Inc., Santa Clara, CA (US)

(72) Inventors: Lara HAWRYLCHAK, Gilroy, CA (US); Kin Pong LO, Fremont, CA (US); Errol C. SANCHEZ, Tracy, CA (US)

(21) Appl. No.: 16/117,011

(22) Filed: Aug. 30, 2018

Related U.S. Application Data
(60) Provisional application No. 62/552,118, filed on Aug. 30, 2017.

(51) Int. Cl. C23C 16/02; C30B 25/10; C30B 33/02; C23C 16/54; C23C 16/56; C23C 16/24; C23C 16/30; C30B 29/06; C30B 29/52; H01L 21/67; H01L 21/02; H01J 37/32; B08B 7/00

(52) U.S. Cl. CPC C23C 16/0227; H01J 2237/335; C30B 33/02; C23C 16/54; C23C 16/56; C23C 16/24; C23C 16/30; C30B 29/06; C30B 29/52; H01L 21/67201; H01L 21/67184; H01L 21/02046; H01L 21/02532; H01L 21/0262; H01L 21/02661; H01J 37/32889; H01J 37/32724; H01J 37/3244; B08B 7/0035; H01J 37/32899; C30B 25/10

(57) ABSTRACT

Implementations of the present disclosure generally relate to an improved vacuum processing system. In one implementation, the vacuum processing system includes a first transfer chamber coupling to at least one vapor phase epitaxy process chamber, a second transfer chamber, a transition station disposed between the first transfer chamber and the second transfer chamber, a plasma-cleaning chamber coupled to the first or second transfer chamber for removing contaminants from a surface of a substrate, and a load lock chamber coupled to the second transfer chamber.

### CROSS-REFERENCE TO RELATED APPLICATION

This application claims benefit of U.S. Provisional Patent Application Ser. No. 62/552,118, filed Aug. 30, 2017, which is hereby incorporated by reference herein.

### FIELD

Implementations of the present disclosure generally relate to an apparatus and a method for cleaning a surface of a substrate.

### BACKGROUND

Integrated circuits are formed in and on silicon and other semiconductor substrates. In the case of single crystal silicon, substrates are made by growing an ingot from a bath of molten silicon, and then sawing the solidified ingot into multiple substrates. An epitaxial silicon layer may then be formed on the monocrystalline silicon substrate to form a defect free silicon layer that may be doped or undoped. Semiconductor devices, such as transistors, may be manufactured from the epitaxial silicon layer. The electrical properties of the formed epitaxial silicon layer are generally better than the properties of the monocrystalline silicon substrate.

Surfaces of the monocrystalline silicon and the epitaxial silicon layer are susceptible to contamination when exposed to typical substrate fabrication facility ambient conditions. For example, a native oxide layer may form on the monocrystalline silicon surface prior to deposition of the epitaxial layer due to handling of the substrates and/or exposure to ambient environment in the substrate processing facility. Additionally, foreign contaminants such as carbon and oxygen species present in the ambient environment may deposit on the monocrystalline surface. The presence of a native oxide layer or contaminants on the monocrystalline silicon surface negatively affects the quality of an epitaxial layer subsequently formed on the monocrystalline surface. It is therefore desirable to pre-clean the substrates in order to remove the surface oxidation and other contaminants before epitaxial layers are grown on the substrates. However, pre-clean processes are often carried out in one or more standalone vacuum process chambers, which may increase substrate handling time and chances of exposing substrates to ambient environment.

Therefore, there is a need in the art to provide an improved substrate processing system for cleaning a substrate surface prior to performing an epitaxial deposition process that minimizes substrate handling time and exposure to ambient environment.

### SUMMARY

This disclosure describes a vacuum processing system, comprising a first transfer chamber coupled to at least one film formation chamber; a second transfer chamber; a plasma oxygen removal chamber coupled to the first or second transfer chamber; a plasma contaminant removal chamber coupled to the first or second transfer chamber; and a load lock chamber coupled to the second transfer chamber.

Also described herein is a method of processing a substrate, comprising removing oxygen from a substrate by a process that includes exposing the substrate to a processing gas comprising NF₃, HF, and radicals; removing contaminants from the substrate by a process that includes exposing the substrate to hydrogen radicals; and forming a film on the substrate by an epitaxy process.

Also described herein is a vacuum processing apparatus, comprising a first transfer chamber coupled to at least one vapor phase epitaxy chamber; a second transfer chamber coupled to the first transfer chamber by one or more pass-through stations; a plasma oxygen removal chamber coupled to the first or second transfer chamber, the plasma oxygen removal chamber comprising a showerhead with a mixing chamber and a gas distributor; a first gas inlet formed through a portion of the showerhead and in fluid communication with the mixing chamber; a second gas inlet formed through a portion of the showerhead and in fluid communication with the mixing chamber; a third gas inlet formed through a portion of the showerhead and in fluid communication with the mixing chamber; and a substrate support with a substrate supporting surface; a cooling channel and one or more resistive heaters embedded in the substrate support; and a lift member disposed in a recess of the substrate supporting surface and coupled through the substrate support to a lift actuator; a plasma contaminant removal chamber coupled to the first or second transfer chamber, the plasma contaminant removal chamber comprising a remote plasma source; a magnetic ion filter; and a substrate support operable to heat a substrate disposed thereon to a temperature between 25 degrees Celsius and 650 degrees Celsius; and a load lock chamber coupled to the second transfer chamber.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a processing sequence in accordance with one implementation of the present disclosure.

FIG. 2 is a cross-sectional view of a cleaning chamber used to perform a reducing process of FIG. 1 in accordance with one implementation of the present disclosure.

FIG. 3 is a perspective view of a substrate support that may be disposed within a substrate processing chamber, such as a processing chamber having a remote plasma source.

FIG. 4 is a cross-sectional view of a portion of the substrate support of FIG. 3.

FIG. 5 illustrates single substrate chemical vapor deposition (CVD) reactor for performing an epitaxial deposition process.

FIG. 6 illustrates a schematic sectional view of a backside heating process chamber for performing an epitaxial deposition process.

FIG. 7 is a schematic cross-sectional view of a CVD chamber for performing an epitaxial deposition process.

FIG. 8 illustrates an exemplary vacuum processing system for performing cleaning and deposition processes as described herein.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

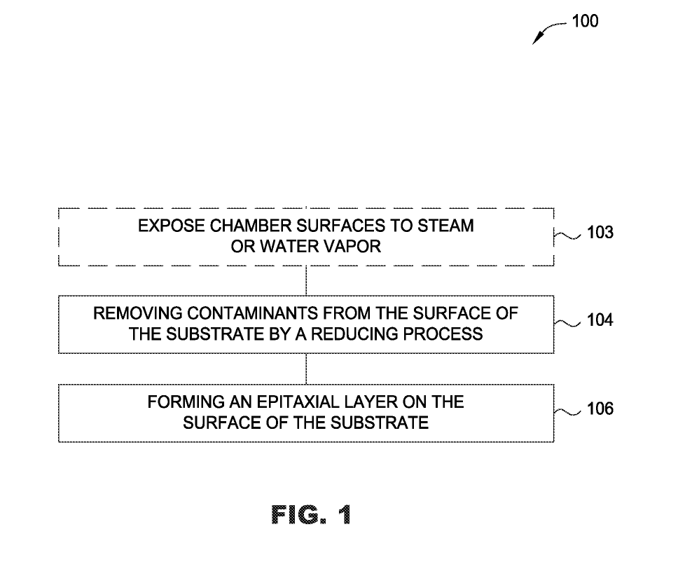

FIG. 1 illustrates a processing sequence 100 in accordance with one implementation of the present disclosure. At 103, an optional chamber conditioning step may be performed in the chamber to be used for operation 104. The operation 104 includes use of a gas containing hydrogen radicals, so the chamber surfaces may be passivated by exposure to steam or water vapor. The steam may be generated ex-situ or in-situ by known methods, and the chamber surfaces may be exposed to the steam for a period of 1 second to 60 seconds, for example about 30 seconds, to yield surfaces with at least slightly improved resistance to hydrogen radicals. During the steam passivation process, an active production substrate may be present in the processing chamber disposed on the substrate support. Alternately, a dummy substrate may be positioned on the substrate support. If the substrate support is made of a material that might react with steam, positioning a substrate on the support during the steam passivation process may reduce reactivity with steam. The substrate may be heated during the steam passivation process to reduce contact between the steam and the substrate. For example, the substrate may be heated to 400 degrees Celsius, or higher, during the steam passivation process.

In box 104, contaminants are removed from the surface of the substrate. In one implementation of box 104, contaminants such as carbon or hydrocarbons are removed from the surface of the substrate using a reducing process. The reducing process may use a hydrogen containing plasma to remove contaminants. The plasma may be formed from a cleaning gas containing hydrogen gas (H₂), helium (He), argon (Ar), ammonia (NH₃), or any combination of these gases. The plasma may be inductively or capacitively coupled, or the plasma may be formed by a microwave source in a processing chamber. The processing chamber may be a remote plasma chamber that is physically separated from the processing chamber where the substrate is disposed.

In one implementation, the plasma is formed using an inductively coupled plasma source that is a remote plasma source (RPS) to perform the reducing process 104. Radicals from the plasma may pass through a passage tube and a gas distribution plate disposed above the substrate. The substrate is positioned on a support at a temperature of about 25 degrees Celsius to about 650 degrees Celsius, such as between about 100 degrees Celsius and about 500 degrees Celsius, in some cases at least about 400 degrees Celsius, in some cases about 400 degrees Celsius. In other cases, the substrate is maintained at a temperature of 500 degrees Celsius to 650 degrees Celsius. The processing pressure may be at subatmospheric pressure, for example about 20 mTorr to about 300 Torr, for example about 100 mTorr to about 300 mTorr, for example about 150 mTorr. Radicals reach the substrate and then react with the surface contaminants to form volatile species that enter the gas phase in the processing chamber and are evacuated. Exemplary processing chambers that can be adapted to perform a reducing process include AKTIV Pre-Clean™, PCxT Reactive Preclean™ (RPC), or Selectra™ chambers, available from Applied Materials, Inc., of Santa Clara, Calif. Chambers from other manufacturers may also be used.

The remote plasma process forms a gas containing hydrogen radicals. As described above, the hydrogen containing plasma is passed through a conduit surrounded by a magnetic field that diverts charged particles while allowing neutral particles, such as hydrogen radicals, and other radicals and molecules, to pass through to the processing region containing the substrate. The substrate is exposed to the gas containing hydrogen radicals to perform the reducing process, which removes contaminants including carbon. The process also leaves the surface of the substrate uniformly hydrogen terminated with minimal defects in the crystal structure at the substrate surface.

In box 106, an epitaxial layer is formed on the surface of the substrate. If cleaned prior, as described above, the surface of the substrate is uniformly oxide and contaminant free which improves the quality of grown epitaxial layers formed on the surface of the substrate. An exemplary epitaxial process may be a selective epitaxial process performed at a temperature that is less than about 800 degrees Celsius, for example about 450 to 650 degrees Celsius. The epitaxial layer may be formed using a high temperature chemical vapor deposition (CVD) process. The epitaxial layer may be crystalline silicon, germanium, or silicon germanium, or any suitable semiconductor material such as a Group III-V compound or a Group II-VI compound. In one exemplary thermal CVD process, processing gases such as chlorosilanes SiHₓCl₄₋ₓ(mono, di, tri, tetra), silanes SiₓH₂ₓ₊₂ (silane, disilane, trisilane, etc.), germanes GeₓH₂ₓ₊₂ (germane, digermane, etc.), hydrogen chloride HCl, chlorine gas Cl₂, or combinations thereof are used to form the epitaxial layer. The processing temperature is under 800 degrees Celsius, such as about 300 degrees Celsius to about 600 degrees Celsius, for example about 450 degrees Celsius, and the processing pressure is between 5 Torr and 600 Torr. An exemplary processing chamber that can be used to perform the epitaxial deposition process is the Centura™ Epi chamber, which is available from Applied Materials, Inc., of Santa Clara, Calif. Chambers from other manufacturers may also be used.

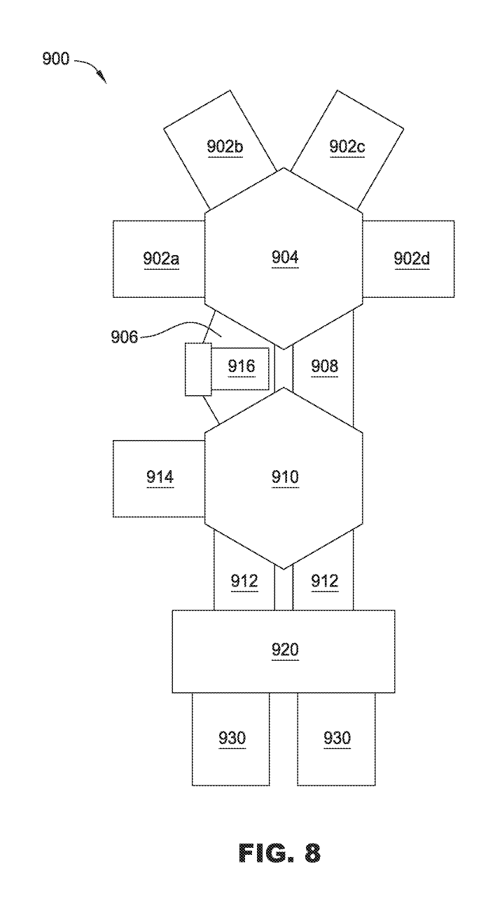

Boxes 103, 104, and 106 may be performed in one processing system, such as a vacuum processing system illustrated in FIG. 8, and further described below. The processes described in boxes 103 and 104 may be repeated as many times as necessary. An optional thermal treatment may also be performed after the process 104, before performing the layer formation process of 106, to remove any residual by-products or contaminants, and to anneal the surface to remove any surface defects. Such an anneal may be performed under a hydrogen atmosphere, optionally including an inert gas such as argon and helium, and may be performed at temperatures of 400 to 800 degrees Celsius and pressures from 1 Torr to 300 Torr.

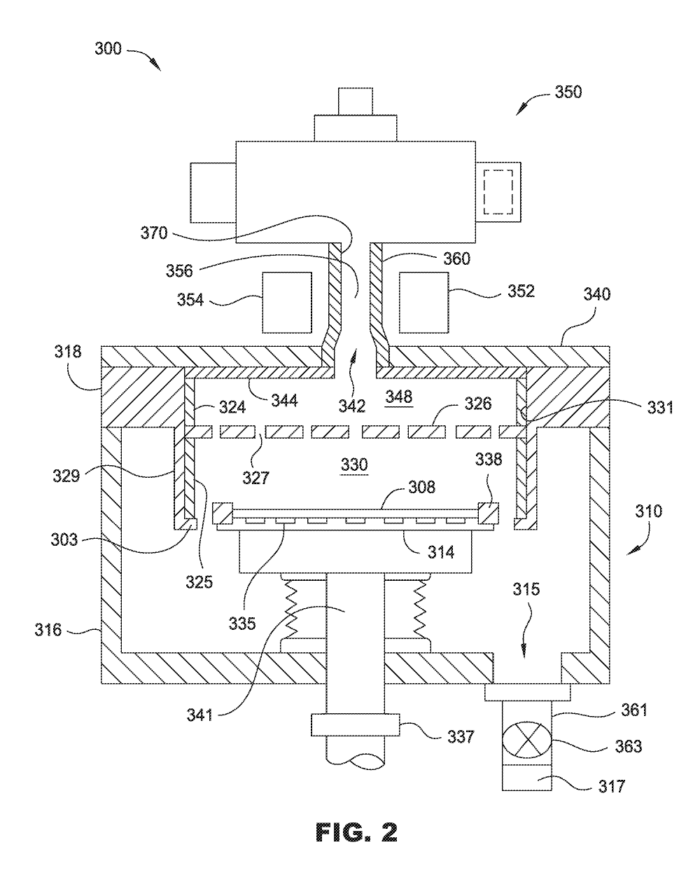

FIG. 2 is a cross sectional view of a processing chamber 300 that can be used to perform at least some of the processes found in box 104, and thus removes contaminants, such as carbon or hydrocarbons accumulated on a surface of a substrate. The processing chamber 300 has a chamber body 310, which includes a chamber enclosure 316, a process kit housing 318, and a lid 340. The chamber enclosure 316 and the lid 340 may be fabricated from aluminum, stainless steel or other suitable materials. The process kit housing 318 may be fabricated from aluminum alloy or other suitable materials. The lid 340 is removably coupled to the chamber enclosure 316 through the process kit housing 318.

The process kit housing 318 may be a ring-shaped housing having a top surface that couples to the lid 340 and a bottom surface that couples to the chamber enclosure 316. The process kit housing 318 has a shield portion 329 extending down from an inner surface 331 of the process kit housing 318. The inner surface 331 of the process kit housing 318 surrounds and supports a gas distribution plate 326 thereon. The gas distribution plate 326 may be a quartz showerhead. A plenum 348 is defined between the gas distribution plate 326 and the lid 340. The gas distribution plate 326 includes a plurality of apertures 327 formed through the thickness of the gas distribution plate 326 to allow gases flowing into the plenum 348 through a port 342. The apertures 327 are evenly distributed across the diameter of the gas distribution plate 326 to ensure uniform distribution of the gases or radicals to the substrate 308. The gases flowing through the apertures 327 are distributed across the substrate 308 disposed in a process region 330 defined between the gas distribution plate 326 and a substrate support 314. The substrate support 314 may include a heater. The shield portion 329 also helps confine electrically neutral radicals within the process region 330. In one example, the shield portion 329 is extended to a location adjacent or below the edge of the substrate support 314.

The processing chamber 300 includes a remote plasma source 350 that is coupled to the port 342 by a conduit 360. The port 342 is formed in the lid 340. The conduit 360 defines an inlet 356, which may have a first inner diameter and a second inner diameter that is larger than the first inner diameter. The first inner diameter may be disposed adjacent to the remote plasma source 350 and the second inner diameter may be disposed adjacent to the lid 340. In one example, first inner diameter may be about 12 mm to about 30 mm, for example about 20 mm, and the second inner diameter may be about 35 mm to about 60 mm, for example about 40 mm.

The conduit 360 is configured to filter ions generated in the remote plasma source 350 before entering the process region 330, while allowing electrically neutral radicals to enter the process region 330. The relative concentration of ions in the process region 330 is thus reduced. In one implementation, the gases flowing through the inlet 356 are filtered by a magnetic field generated by one or more magnets disposed adjacent to the conduit 360. The magnets generate a magnetic field across the conduit 360 to filter charged particles entrained with the reactive radicals flowing from the remote plasma source 350.

In the implementation depicted in FIG. 2, a first magnet 352 and a second magnet 354 are disposed adjacent to the conduit 360. The first magnet 352 and second magnet 354 may be permanent magnets or electromagnets. The magnets 352, 354 may be disposed opposite from each other across the first inner diameter of the conduit 360. For example, the magnets 352, 354 may be adhered or secured on opposite sides of an outer periphery of the conduit 360. The magnets 352, 354 may alternately be secured to the chamber lid 340 or other components of the chamber body 310. The relative distance between the opposed magnet and the inlet 356 formed within the conduit 360 affects the strength of the magnetic field passing through the inlet 356, and thereby affects the filtering efficiency. The magnetic field may also be adjusted by using different magnets, i.e., replacing magnets 352, 354 with different strength. The passing charged particles are drawn in contact with an inner surface 370 of the conduit 360 and become electrically neutral, non-ionic species. As such, the filtered, electrically neutral radicals are delivered to the surface of the substrate to react with and clean contaminants thereon.

In some implementations, the ions may be further filtered by providing a quartz surface in the flow path of the process gases (i.e., radicals and ions) passing into the chamber body 310. For example, the inner surface 370 of the conduit 360 defining the inlet 356 may be entirely or partially coated or fabricated from quartz. Additionally, the surfaces defining the plenum 348 and/or gas distribution plate 326 may also be entirely or at least partially coated or fabricated from quartz. For example, in the implementation of FIG. 2, a top liner 324 may be disposed along the inner surface 331 of the process kit housing 318. The top liner 324 may have a ring-shaped body surrounding the plenum 348, an inner surface thereof defining the outer boundary of the plenum 348. The top liner 324 may be made of quartz. The top liner 324 may rest on the gas distribution plate 326, or may be supported by any other suitable securing approach.

A liner plate 344 may be disposed along the bottom surface of the lid 340. The liner plate 344 may be coated with, or fabricated from, quartz. The liner plate 344 defines the upper boundary of the plenum 348. Therefore, the liner plate 344, the top liner 324, and the gas distribution plate 326 define the plenum 348. A bottom liner 325 may be disposed along the inner surface 331 of the process kit housing 318. The bottom liner 325 may have a ring-shaped body, and surrounds the process region 330 when assembled for operation, an inner surface thereof defining the outer boundary of the process region 330. The bottom liner 325 may be coated with, or fabricated from, quartz. The bottom liner 325 may be supported by the shield portion 329. In one example as shown, a ledge 303 extends radially inward at an end of the shield portion 329 to support the bottom liner 325. Therefore, the conduit 360, the liner plate 344, the top liner 324, the bottom liner 325, and the gas distribution plate together provide a quartz surface along the flow path of the process gases. These components reduce the recombination of radicals as compared to other chamber materials (e.g., aluminum). As such, the process gas is substantially reduced in content of charged particles, and may be predominantly neutral species such as radicals and molecules, when flowing through the gas distribution plate 326 into the process region 330. The electrically neutral radicals will remain reactive when they reach and react with a surface of the substrate disposed on the substrate support to remove unwanted materials, for example carbon contaminants, from the surface of the substrate.

A substrate support 314 is disposed in the process region 330 of the chamber body 310. The substrate support 314 is coupled to a bottom of the chamber enclosure 316 through a central shaft 341. The substrate support 314 has a substrate supporting surface for supporting the substrate 308 thereon during a process, such as the processes described above with respect to boxes 103 and 104. An optional focus ring 338 may be disposed on the substrate support 314 around the outer periphery of the substrate supporting surface. The focus ring 338 confines plasma or neutral species in an area above the substrate 308 during process. The focus ring 338 may be fabricated from quartz.

The substrate support 314 may be fabricated from aluminum with a plurality of sapphire contacts (not shown) disposed on the substrate supporting surface to minimize contact between the substrate supporting surface and a substrate disposed on the sapphire contacts. The substrate support 314 is actuated by a driving unit 337 to move vertically between a loading position and a processing position. The substrate support 314 may have one or more heating elements 335 embedded therein to provide uniform thermal energy to the substrate supporting surface. Suitable heating elements 335 may include resistive heaters, thermoelectric devices, or conduits for flowing heat transfer fluid, among other heating devices. The heating elements 335 allow the temperature of the substrate 308 to be maintained at a temperature range of about 25° C. to about 500° C., for example about 300° C. to about 350° C., about 350° C. to about 450° C., or about 450° C. to about 500° C. In some implementations, the substrate support 314 may have cutouts formed through the peripheral edge of the substrate supporting surface so that a substrate handler (not shown) can manipulate the substrate 308 from the edge of the substrate when the substrate support 314 is positioned at the loading position. During the cleaning process, the substrate support 314, with substrate 308 disposed thereon, is positioned at the processing position, which is a desired position for processing the substrate 308.

The processing chamber 300 includes a pump 317. The pump 317 is connected to the chamber body 310 through a foreline 361. The foreline 361 connects to the chamber body 310 at an opening 315 formed at the bottom of the enclosure 316. The chamber 300 also includes a throttle valve 363 disposed in the foreline 361. The throttle valve 363 is operated to open and close to whatever extent is necessary to maintain the pressure in the processing chamber 300 in a desired vacuum range for the plasma cleaning process being run. The pump 317 and the throttle valve 363 control the pressure inside the chamber body 310 from between about 0.005 Torr and 750 Torr, for example about 40 Torr to about 500 Torr. In one example, the pump 317 is a dry pump that maintains the pressure inside the processing chamber 300 at an exemplary pressure range of about 0.1 Torr to about 40 Torr, for example about 30 Torr. In one example, the pump 317 is a low pressure pump that maintains the pressure inside the processing chamber 300 at an exemplary pressure range of about 100 mTorr to about 500 mTorr, for example about 150 mTorr. In some examples, the pump 317 is a turbo pump that maintains the pressure inside the processing chamber 300 at an exemplary pressure range of about 20 mTorr to 50 mTorr.

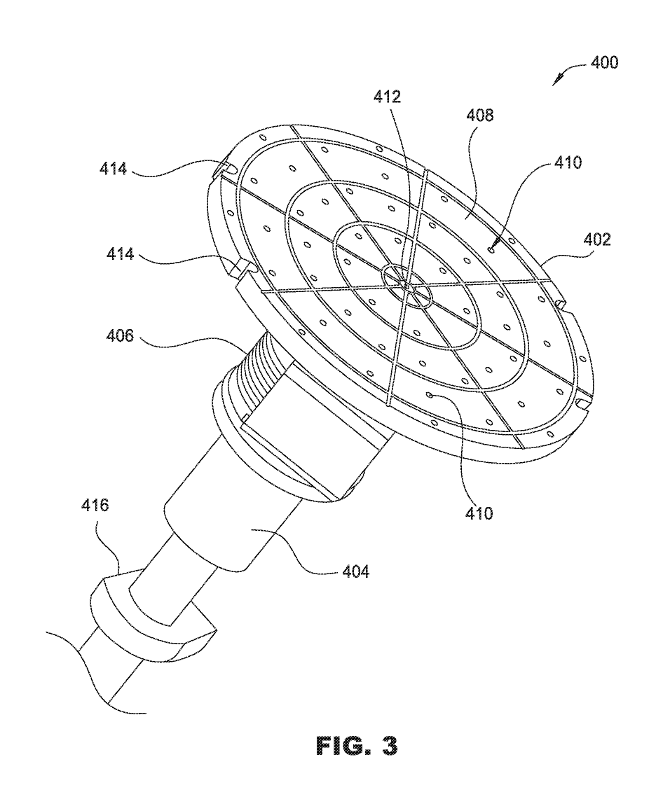

FIG. 3 is a perspective view of a substrate support 400 that may be disposed within a substrate processing chamber, such as a processing chamber having a remote plasma source (RPS). The substrate support 400 may be used in the processing chamber 300 instead of the substrate support 314.

The substrate support 400 generally includes a support body 402 and a shaft 404 coupled to the support body 402 through a bellows 406. The bellows 406 is coupled to a bottom of the support body 402. In one example, the bellows 406 is attached in a vacuum-tight manner to a bottom of the substrate processing chamber. A driving unit 416 may be coupled to the bellows 406 through the shaft 404 to allow vertical motion of the support body 402 relative to the substrate processing chamber. In some implementations, the driving unit 416 may be configured to rotate the shaft 404 and thus the support body 402.

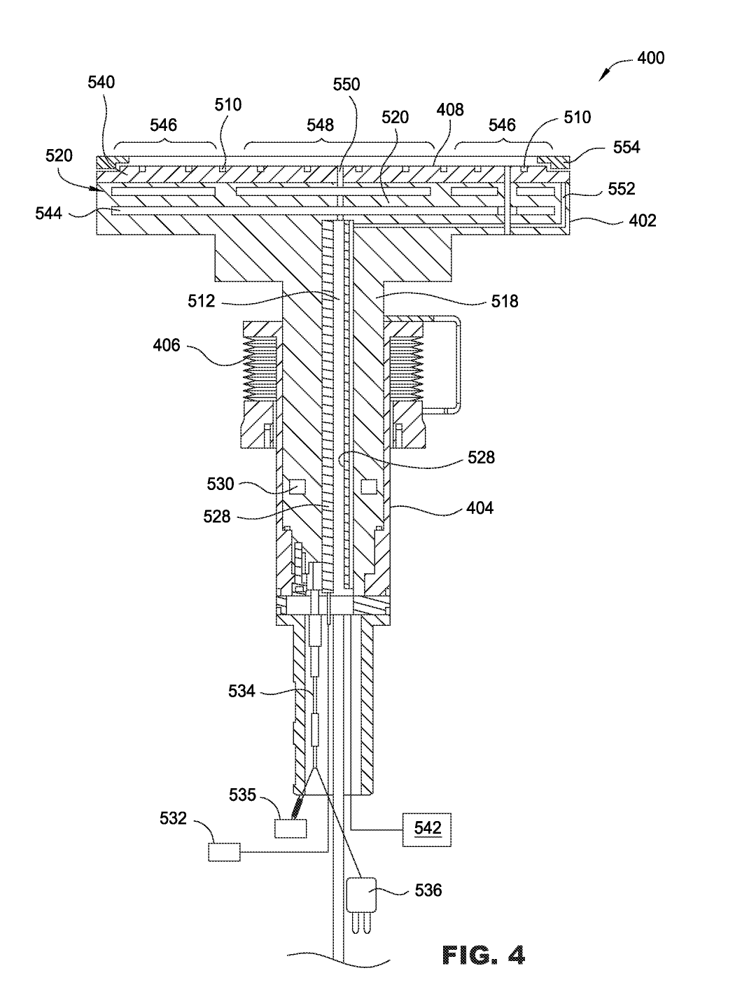

The support body 402 has a substrate supporting surface 408. The support body 402 has one or more heating elements 520 (see FIG. 4) embedded or contained therein to provide uniform thermal energy to a substrate to be disposed on the substrate supporting surface 408 during a process, such as a plasma cleaning process. The heating elements 520 may be arranged in an azimuthally symmetric pattern to ensure uniform heating of the substrate. Suitable heating elements may include resistive heaters, thermoelectric devices, or conduits for flowing heat transfer fluid, among other heating devices. In one example, the heating elements are resistive heating coils. The heating elements allow the temperature of the substrate to be maintained at a temperature range of about 25° C. to about 650° C., or greater, for example about 300° C. to about 350° C., about 350° C. to about 450° C., about 450° C. to about 550° C., about 550° C. to about 650° C., or higher.

The substrate supporting surface 408 has a plurality of contact points 410 on which the substrate rests during processing in the substrate processing chamber. The contact points 410 are uniformly distributed over the substrate supporting surface 408. In one implementation, the contact points 410 are arranged in concentric circles about a central point 412 of the support body 402. Additionally or alternatively, the contact points 410 may be arranged in an azimuthally symmetric pattern to ensure uniform processing of the substrate. The contact points 410 may be in the form of protrusions or bumps. The protrusions or bumps provide minimized contact surface area to prevent the substrate from directly contacting the substrate supporting surface 408 while maintaining a gap between the backside of the substrate and the support body 402 for uniform heating of the substrate. In one implementation, the contact points 410 are sapphire balls.

The support body 402 may have a plurality of cutouts 414 disposed at the peripheral edge of the support body 402. The cutouts are formed through the entire thickness of the support body, i.e., from the substrate supporting surface 408 to a backside of the support body 402. The cutouts 414 may be equally spaced apart around the periphery of the support body 402. In one embodiment, four cutouts 414 are disposed symmetrically at the peripheral edge of the support body 402. The cutouts 414 are sized so that a substrate handler (not shown) can manipulate the substrate from the edge of the substrate when the support body 402 is positioned at a loading position.

The support body 402 may be fabricated from ceramic, aluminum, or other suitable material such as aluminum nitride. The shaft 404 may be fabricated from ceramic, such as aluminum nitride, aluminum oxide, or doped ceramics such as alumina doped with titanium nitride or chromium nitride, doped aluminum oxide, doped boron-nitride and the like. In one embodiment, the shaft 404 is formed from about 95% pure aluminum nitride to enhance thermal conductivity of the shaft 404. In one embodiment, the shaft 404 and the support body 402 may be fabricated from the same material.

FIG. 4 is a cross-sectional view of a portion of the substrate support 400 of FIG. 3. The support body 402 has a plurality of cavities 510 formed in the substrate supporting surface 408 for receiving contact points 410, such as sapphire balls. The shaft 404 is hollow having a sidewall 518 defining a central opening 512 therein. The central opening 512 allows for a power line 528 to pass through. One end of the power line 528 is connected the one or more heating elements 520, while the other end of the power line 528 is connected to a heating power source 532, such as a DC or AC power source.

The shaft 404 may include a channel 530 connecting to a cooling fluid source (not shown). The channel 530 may be disposed within any desired location of the shaft 404 for circulating a cooling fluid from the cooling fluid source to control the temperature of the shaft 404, and thus the support body 402 and the temperature of the substrate placed thereon during a process.

The substrate support 400 may include a thermocouple 534 disposed in the substrate support 400 to measure a temperature, such as the temperature of the substrate support 400, the substrate supporting surface 408, or the temperature of the substrate when disposed on the substrate supporting surface 408. The thermocouple 534 may be any suitable thermocouple design, such as a thermocouple probe or the like. The thermocouple 534 may be coupled to a temperature controller 535, which may control the power supply 536 based on the temperature measured by the thermocouple 534.

In some embodiments, the substrate support 400 includes a puck 540 disposed on the support body 402 forming the substrate supporting surface 408. The puck 540 may be made of a dielectric material and coupled to a power source 542 in order to function as an electrostatic chuck.

In some embodiments the support body 402 may include a coolant channel 544 formed therein. The coolant channel 544 may be coupled to a fluid source (not shown) that circulates a cooling fluid therethrough. In some embodiments, the heating elements 520 comprise a multi zone heater that includes an outer zone 546 and an inner zone 548 that may be controlled independently. A purge gas inlet 550 and outlet 552 may be provided in the substrate support 400. The inlet 550 and outlet 552 may be utilized to supply a backside gas to a substrate on the substrate supporting surface 408. In some embodiments, an edge ring 554 may be provided over the substrate supporting surface 408.

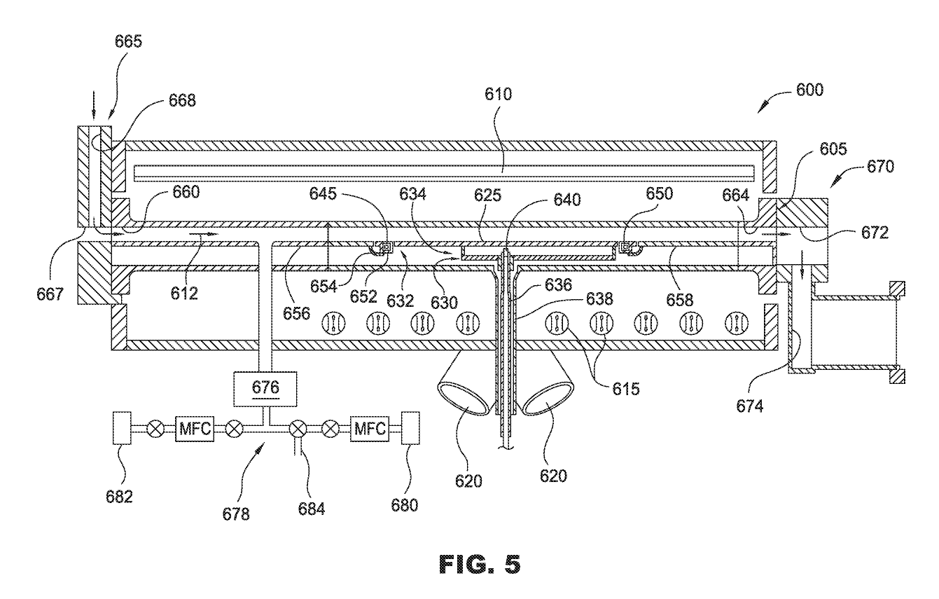

FIG. 5 illustrates single substrate chemical vapor deposition (CVD) reactor 600, including a quartz process or reaction chamber 605, according to one embodiment. The reactor 600 may be utilized for CVD of a number of different materials, including SiGe and Ge films as disclosed herein. Moreover, the illustrated reactor 600 can accomplish multiple deposition steps in the same chamber 605, as will be apparent from the discussion below.

The chamber 500 may generally have the shape of a rectangular box in plan view (not shown). A plurality of radiant heat sources is supported outside the chamber 605 to provide heat energy in the chamber 605 without appreciable absorption by walls of the chamber 605. While the embodiments are described in the context of a “cold wall” CVD reactor for processing semiconductor substrates, it will be understood that the methods described herein will have utility in conjunction with other heating/cooling systems, such as those employing inductive or resistive heating.

The radiant heat sources comprise an upper heating assembly of elongated tube-type radiant heating elements 610. The upper heating elements 610 are preferably disposed in spaced-apart parallel relationship and also substantially parallel with a reactant gas flow path (shown by arrow 612) through the chamber 605. A lower heating assembly comprises similar elongated tube-type radiant heating elements 615 positioned below the chamber 605, and oriented transverse to the upper heating elements 610. A portion of the radiant heat is diffusely reflected into the chamber 605 by rough specular reflector plates (not shown) above and below the upper and lower lamps 610, 615, respectively. Additionally, a plurality of spot lamps 620 supply concentrated heat to the underside of the substrate support structure (described below), to counteract a heat sink effect created by cold support structures extending through the bottom of the chamber 605. Each of the elongated tube type heating elements 610, 615 is preferably a high intensity tungsten filament lamp producing radiant heat energy transmitted through the walls of the chamber 605 without appreciable absorption. As is known in the art of semiconductor processing equipment, the power of the various lamps 610, 615, 620 can be controlled independently or in grouped zones in response to temperature sensors.

A workpiece, comprising a silicon substrate 625, is shown supported within the chamber 605 upon a substrate support structure 630. The illustrated support structure 630 includes a substrate holder 632, upon which the substrate 625 rests, and a support spider 634. The spider 634 is mounted to a shaft 636, which extends downwardly through a tube 638 extending through the chamber lower wall. The tube 638 communicates with a source of purge gas which can flow during processing of a substrate. The purge gas may be utilized to inhibit process gases from entering the lower section of the chamber 605. The purge gas may also flow horizontally beneath the substrate 625.

A plurality of temperature sensors is positioned in proximity to the substrate 625. The temperature sensors may take a variety of forms, such as optical pyrometers or thermocouples. In the illustrated embodiment, the temperature sensors comprise thermocouples, including a first or central thermocouple 640, suspended below the substrate holder 632 in any suitable fashion. The central thermocouple 640 passes through the spider 634 in proximity to the substrate holder 632. The reactor 600 further includes a plurality of secondary or peripheral thermocouples, also in proximity to the substrate 625, including a leading edge or front thermocouple 645, a trailing edge or rear thermocouple 650, and a side thermocouple (not shown). Each of the peripheral thermocouples is housed within a slip ring 652, which surrounds the substrate holder 632 and the substrate 625. Each of the central and peripheral thermocouples are connected to a temperature controller, which sets the power of the various heating elements 610, 615, 620 in response to the readings of the thermocouples.

In addition to housing the peripheral thermocouples, the slip ring 652 absorbs and emits radiant heat during high temperature processing. The slip ring 652 may be utilized to compensate for a greater heat loss or absorption at the substrate edges, a phenomenon which is known to occur due to a greater ratio of surface area to volume in regions near the substrate edges. By minimizing edge losses, slip ring 652 can reduce the risk of radial temperature non-uniformities across the substrate 625. The slip ring 652 can be suspended by any suitable means. For example, the illustrated slip ring 652 rests upon support members 654, which extend from a front chamber divider 656, and a rear chamber divider 658. The dividers 656, 658 desirably are formed of quartz. In some arrangements, the rear divider 658 can be omitted.

The illustrated chamber 605 includes an inlet 660 for the injection of reactant and carrier gases, and the substrate 625 can also be received therethrough. An outlet 664 is on the opposite side of the chamber 605, with the substrate support structure 630 positioned between the inlet 660 and outlet 664.

An inlet component 665 is fitted to the chamber 605, adapted to surround the inlet 660, and includes a horizontally elongated slot 667 through which the substrate 625 can be inserted. A generally vertical inlet 668 receives gases from gas sources and communicates such gases with the slot 667 and the inlet 660. While not separately illustrated in FIG. 5, the gas sources may include hydrogen, silicon and germanium precursors, and a controller (e.g., preprogrammed computer) that controls a sequence of steps as described herein, including flowing the surface active compound into the chamber during a cool down step prior to Si and/or Ge deposition. The inlet 668 can include gas injectors designed to maximize uniformity of gas flow for the single-substrate reactor.

An outlet component 670 similarly mounts to the chamber 605 such that an exhaust opening 672 aligns with the outlet 664 and leads to exhaust conduits 674. The conduits 674, in turn, can communicate with suitable vacuum means (not shown) for exhausting process gases from the chamber 605. In one embodiment, process gases are drawn through the chamber 605 and a downstream scrubber (not shown). A pump or fan is preferably included to aid in drawing process gases through the chamber 605, and to evacuate the chamber for reduced pressure processing, i.e., below atmospheric pressure but above ultra-high vacuum pressure ranges, as discussed below.

The illustrated reactor 600 also includes a source 676 of excited species, positioned upstream from the chamber 605. The excited species source 676 of the illustrated embodiment comprises a remote plasma generator, including a magnetron power generator and an applicator along a gas line 678. In the illustrated embodiment, microwave energy from a magnetron is coupled to a flowing gas in an applicator along the gas line 678. A source of precursor gases 680 is coupled to the gas line 678 for introduction into the excited species source 676. A source of carrier gas 682 is also coupled to the gas line 678. One or more branch lines 684 can also be provided for additional reactants. As is known in the art, the gas sources 680, 682 can comprise gas tanks, bubblers, etc., depending upon the form and volatility of the reactant species. Each gas line can be provided with a separate mass flow controller (MFC) and valves, as shown, to allow selection of relative amounts of carrier and reactant species introduced to the source 676 and thence into the chamber 605. The excited species source 676 can be employed for plasma enhanced deposition, but also may be utilized for exciting etchants for cleaning the chamber 605 of excess deposition when no substrate is in the chamber 605.

The total volume capacity of the single-substrate process chamber 605 designed for processing 200 mm substrates, for example, is less than about 30 liters, such as less than about 20 liters, and in one embodiment is less than about 10 liters. The illustrated chamber 605 has a capacity of about 7.5 liters. Because the illustrated chamber 605 is partitioned by the dividers 656, 658, substrate holder 632, ring 652, and the purge gas flowing from the tube 638, the effective volume through which process gases flow is around half the total volume (e.g., about 3.77 liters in the illustrated embodiment). It is understood that the volume of the single-substrate chamber 605 can be different, depending upon the size of the substrates for which the chamber 605 is designed to accommodate. For example, a single-substrate processing chamber 605 for 300 mm substrates has a capacity of less than about 100 liters, such as about 60 liters, and in one embodiment is less than about 30 liters. In one example, the single-substrate processing chamber 605 for processing a 300 mm substrate has a total volume of about 24 liters, with an effective volume of about 12 liters.

Deposition temperatures for a Ge-containing layer are typically in the range of about 250 degrees Celsius (C) to about 600 degrees C., for example about 300 degrees C. to about 450 degrees C. The total pressure in the single-substrate processing chamber 605 is in the range of about 10-5 Torr to about 800 Torr. In some embodiments, the pressure is about 200 mTorr to about 760 Torr, such as about 1 Torr to about 200 Torr, for example about 1 Torr to about 60 Torr.

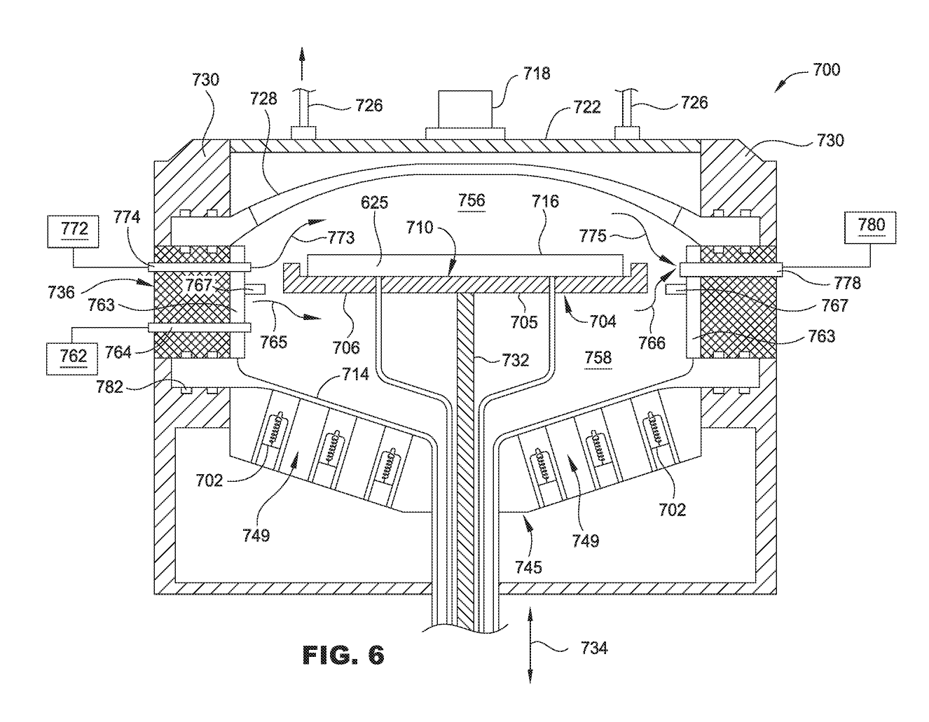

FIG. 6 illustrates a schematic sectional view of a backside heating process chamber 700 configured for low pressure epitaxial deposition according to one embodiment. The process chamber 700 may be used to process one or more substrates, including the deposition of a material on an upper surface of a substrate 625. The process chamber 700 may include an array of radiant heating lamps 702 for heating, among other components, a back side 704 of a substrate support 706 disposed within the process chamber 700. The substrate support 706 may be a disk-like substrate support 706 as shown, or may be a ring-like substrate support (having a central opening), which supports the substrate from the edge of the substrate to facilitate exposure of the substrate to the thermal radiation of the lamps 702.

The substrate support 706 is located within the process chamber 700 between an upper dome 728 and a lower dome 714. The upper dome 728, the lower dome 714 and a base ring 736 that is disposed between the upper dome 728 and lower dome 714 generally define an internal region of the process chamber 700. The substrate 625 (not to scale) is transferred into the process chamber 700 and positioned onto the substrate support 706 through a loading port not shown in this view.

The substrate support 706 is supported by a central shaft 732, which moves the substrate 625 in a vertical direction 734 during loading and unloading, and in some instances, processing of the substrate 625. The substrate support 706 is shown in an elevated processing position in FIG. 6, but may be vertically traversed by an actuator (not shown) coupled to the central shaft 732 to a loading position below the processing position. When lowered below the processing position, lift pins 705 contact the substrate 625 and raise the substrate 625 from the substrate support 706. A robot (not shown) may then enter the process chamber 700 to engage and remove the substrate 625 therefrom though the loading port. The substrate support 706 then may be actuated vertically to the processing position to place the substrate 625, with its device side 716 facing up, on a front side 710 of the substrate support 706.

The substrate support 706, while located in the processing position, divides the internal volume of the process chamber 700 into a process gas region 756 that is above the substrate 625, and a purge gas region 758 below the substrate support 706. The substrate support 706 is rotated during processing by the central shaft 732 to minimize the effect of thermal and process gas flow spatial anomalies within the process chamber 700 and thus facilitate uniform processing of the substrate 625. The substrate support 706 may be formed from silicon carbide or graphite coated with silicon carbide to absorb radiant energy from the lamps 702 and conduct the radiant energy to the substrate 625.

In general, the central window portion of the upper dome 728 and the bottom of the lower dome 714 are formed from an optically transparent material such as quartz. The thickness and the degree of curvature of the upper dome 728 may be configured to provide a flatter geometry for uniform flow uniformity in the process chamber.

The array of lamps 702 can be disposed adjacent to and beneath the lower dome 714 in a specified, optimal desired manner around the central shaft 732 to independently control the temperature at various regions of the substrate 625 as the process gas passes over, which facilitates the deposition of a material onto the upper surface of the substrate 625. While not discussed here in detail, the deposited material may include gallium arsenide, gallium nitride, or aluminum gallium nitride. In some embodiments, an array of radiant heating lamps, such as the lamps 702, may be disposed over the upper dome 728.

The lamps 702 may be configured to include bulbs configured to heat the substrate 625 to a temperature within a range of about 200 degrees C. to about 1600 degrees C. Each lamp 702 is coupled to a power distribution board (not shown) through which power is supplied to each lamp 702. The lamps 702 are positioned within a lamphead 745 which may be cooled during or after processing by, for example, a cooling fluid introduced into channels 749 located between the lamps 702. The lamphead 745 conductively and radiatively cools the lower dome 714 due in part to the close proximity of the lamphead 745 to the lower dome 714. The lamphead 745 may also cool the lamp walls and walls of reflectors (not shown) around the lamps. Alternatively, the lower dome 714 may be cooled by a convective approach. Depending upon the application, the lamphead 745 may or may not be in contact with the lower dome 714.

A circular shield 767 may be optionally disposed around the substrate support 706 and surrounded by a liner assembly 763. The shield 767 prevents or minimizes leakage of heat/light noise from the lamps 702 to the device side 716 of the substrate 625 while providing a pre-heat zone for the process gases. The shield 767 may be made from CVD SiC, sintered graphite coated with SiC, grown SiC, opaque quartz, coated quartz, or any similar, suitable material that is resistant to chemical breakdown by process and purging gases.

The liner assembly 763 is sized to be nested within or surrounded by an inner circumference of the base ring 736. The liner assembly 763 shields the processing volume (i.e., the process gas region 756 and purge gas region 758) from metallic walls of the process chamber 700. The metallic walls may react with precursors and cause contamination in the processing volume. While the liner assembly 763 is shown as a single body, the liner assembly 763 may include one or more liners with different configurations.

As a result of backside heating of the substrate 625 from the substrate support 706, the use of an optical pyrometer 718 for temperature measurements/control on the substrate support can be performed. This temperature measurement by the optical pyrometer 718 may also be done on the device side 716 of the substrate 625, having an unknown emissivity, since heating the substrate front side 710 in this manner is emissivity independent. As a result, the optical pyrometer 718 can only sense radiation from the hot substrate 625 that conducts heat from the substrate support 706, with minimal background radiation from the lamps 702 directly reaching the optical pyrometer 718.

A reflector 722 may be optionally placed outside the upper dome 728 to reflect light that is radiating off the substrate 625 back onto the substrate 625. The reflector 722 may be secured to the upper dome 728 using a clamp ring 730. The reflector 722 can be made of a metal such as aluminum or stainless steel. The efficiency of the reflection can be improved by coating a reflector area with a highly reflective coating such as gold. The reflector 722 can have one or more channels 726 connected to a cooling source (not shown). The channels 726 connect to a passage (not shown) formed on a side of the reflector 722 for cooling the reflector 722. The passage is configured to carry a flow of a fluid such as water and may run horizontally along the side of the reflector 722 in any desired pattern covering a portion or entire surface of the reflector 722.

Process gas supplied from a process gas supply source 772 is introduced into the process gas region 756 through a process gas inlet 774 formed in the sidewall of the base ring 736. The process gas inlet 774 is configured to direct the process gas in a generally radially inward direction. During the film formation process, the substrate support 706 may be located in the processing position, which is adjacent to and at about the same elevation as the process gas inlet 774, allowing the process gas to flow up and round along flow path 773 across the upper surface of the substrate 625 in a laminar flow. The process gas exits the process gas region 756 (along flow path 775) through a gas outlet 778 located on the side of the process chamber 700 opposite the process gas inlet 774. Removal of the process gas through the gas outlet 778 may be facilitated by a vacuum pump 780 coupled thereto. As the process gas inlet 774 and the gas outlet 778 are aligned with each other and disposed approximately at the same elevation, it is believed that such a parallel arrangement, when combined with a flatter upper dome 728 enables a generally planar, uniform gas flow across the substrate 625. Further radial uniformity may be provided by the rotation of the substrate 625 through the substrate support 706.

A purge gas may be supplied from a purge gas source 762 to the purge gas region 758 through an optional purge gas inlet 764 (or through the process gas inlet 774) formed in the sidewall of the base ring 736. The purge gas inlet 764 is disposed at an elevation below the process gas inlet 774. If the circular shield 767 or a pre-heat ring (not shown) is used, the circular shield or the pre-heat ring may be disposed between the process gas inlet 774 and the purge gas inlet 764. In either case, the purge gas inlet 764 is configured to direct the purge gas in a generally radially inward direction. During the film formation process, the substrate support 706 may be located at a position such that the purge gas flows down and round along flow path 765 across the back side 704 of the substrate support 706 in a laminar flow. Without being bound by any particular theory, the flowing of the purge gas is believed to prevent or substantially avoid the flow of the process gas from entering into the purge gas region 758, or to reduce diffusion of the process gas entering the purge gas region 758 (i.e., the region under the substrate support 706). The purge gas exits the purge gas region 758 (along flow path 766) and is exhausted out of the process chamber through the gas outlet 778, which is located on the side of the process chamber 700 opposite the purge gas inlet 764.

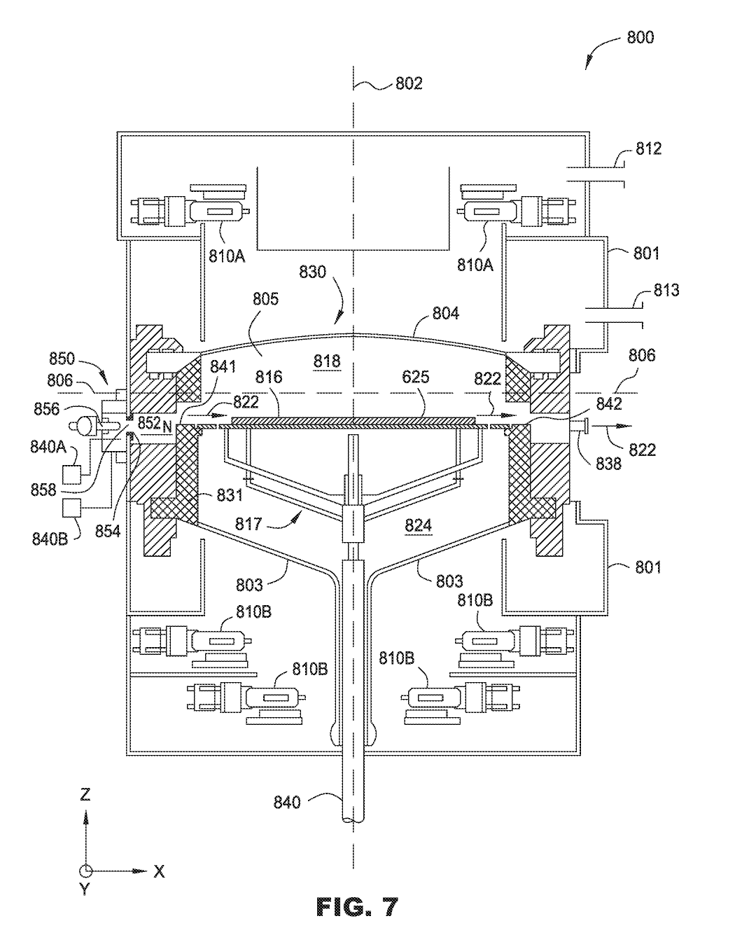

FIG. 7 is a schematic cross-sectional view of a CVD or epitaxial deposition chamber 800, which may be part of a CENTURA® integrated processing system available from Applied Materials, Inc., of Santa Clara, Calif. The deposition chamber 800 includes housing structure 801 made of a process resistant material, such as aluminum or stainless steel, for example 316 L stainless steel. The housing structure 801 encloses various functioning elements of the chamber 800, such as a quartz chamber 830, which includes an upper chamber 805, and a lower chamber 824, in which a processing volume 818 is contained. Reactive species are provided to the quartz chamber 830 by a gas distribution assembly 850, and processing byproducts are removed from processing volume 818 by an outlet 838, which is typically in communication with a vacuum source (not shown).

A substrate support 817 is adapted to receive a substrate 625 that is transferred to the processing volume 818. The substrate support 817 is disposed along a longitudinal axis 802 of the chamber 800. The substrate support may be made of a ceramic material or a graphite material coated with a silicon material, such as silicon carbide, or other process resistant material. Reactive species from precursor reactant materials are applied to surface 816 of the substrate 625, and byproducts may be subsequently removed from the surface 816. Heating of the substrate 625 and/or the processing volume 818 may be provided by radiation sources, such as upper lamp modules 810A and lower lamp modules 810B.

In one embodiment, the upper lamp modules 810A and lower lamp modules 810B are infrared (IR) lamps. Non-thermal energy or radiation from lamp modules 810A and 810B travels through upper quartz window 804 of upper quartz chamber 805, and through the lower quartz portion 803 of lower quartz chamber 824. Cooling gases for upper quartz chamber 805, if needed, enter through an inlet 812 and exit through the outlet port 813. Precursor reactant materials, as well as diluent, purge and vent gases for the chamber 800, enter through gas distribution assembly 850 and exit through outlet 838. While the upper quartz window 804 is shown as being curved or convex, the upper quartz window 804 may be planar or concave as the pressure on both sides of the upper quartz window 804 is substantially the same (i.e., atmospheric pressure).

The low wavelength radiation in the processing volume 818, which is used to energize reactive species and assist in adsorption of reactants and desorption of process byproducts from the surface 816 of substrate 625, typically ranges from about 0.8 μm to about 1.2 μm, for example, between about 0.95 μm to about 1.05 μm, with combinations of various wavelengths being provided, depending, for example, on the composition of the film which is being epitaxially grown.

The component gases enter the processing volume 818 via gas distribution assembly 850. Gas flows from the gas distribution assembly 850 and exits through port 838 as shown generally at 822. Combinations of component gases, which are used to clean/passivate a substrate surface, or to form the silicon and/or germanium-containing film that is being epitaxially grown, are typically mixed prior to entry into the processing volume. The overall pressure in the processing volume 818 may be adjusted by a valve (not shown) on the outlet port 838. At least a portion of the interior surface of the processing volume 818 is covered by a liner 831. In one embodiment, the liner 831 comprises a quartz material that is opaque. In this manner, the chamber wall is insulated from the heat in the processing volume 818.

The temperature of surfaces in the processing volume 818 may be controlled within a temperature range of about 200° C. to about 600° C., or greater, by the flow of a cooling gas, which enters through an inlet 812 and exits through an outlet port 813, in combination with radiation from upper lamp modules 810A positioned above upper quartz window 804. The temperature in the lower quartz chamber 824 may be controlled within a temperature range of about 200° C. to about 600° C. or greater, by adjusting the speed of a blower unit which is not shown, and by radiation from the lower lamp modules 8106 disposed below lower quartz chamber 824. The pressure in the processing volume 818 may be between about 0.1 Torr to about 600 Torr, such as between about 5 Torr to about 30 Torr.

The temperature on the substrate 625 surface 816 may be controlled by power adjustment to the lower lamp modules 810B in lower quartz chamber 824, or by power adjustment to both the upper lamp modules 810A overlying upper quartz chamber 804, and the lower lamp modules 810B in lower quartz chamber 824. The power density in the processing volume 818 may be between about 40 W/cm² to about 400 W/cm², such as about 80 W/cm² to about 120 W/cm².

In one aspect, the gas distribution assembly 850 is disposed normal to, or in a radial direction 806 relative to, the longitudinal axis 802 of the chamber 800 or substrate 625. In this orientation, the gas distribution assembly 850 is adapted to flow process gases in a radial direction 806 across, or parallel to, the surface 816 of the substrate 625. In one processing application, the process gases are preheated at the point of introduction to the chamber 800 to initiate preheating of the gases prior to introduction to the processing volume 818, and/or to break specific bonds in the gases. In this manner, surface reaction kinetics may be modified independently from the thermal temperature of the substrate 625.

In operation, precursors to form Si and SiGe blanket or selective films are provided to the gas distribution assembly 850 from the one or more gas sources 840A and 840B. IR lamps 856 (only one is shown in FIG. 7) may be utilized to heat the precursors within the gas distribution assembly 850 as well as along the flow pat 822. The gas sources 840A, 840B may be coupled the gas distribution assembly 850 in a manner configured to facilitate introduction zones within the gas distribution assembly 850, such as a radial outer zone and a radial inner zone between the outer zones when viewed in from a top plan view. The gas sources 840A, 840B may include valves (not shown) to control the rate of introduction into the zones.

The gas sources 840A, 840B may include silicon precursors such as silanes, including silane (SiH₄), disilane (Si₂H₆,), dichlorosilane (SiH₂Cl₂), hexachlorodisilane (Si₂Cl₆), dibromosilane (SiH₂Br₂), higher order silanes, derivatives thereof, and combinations thereof. The gas sources 840A, 840B may also include germanium containing precursors, such as germane (GeH₄), digermane (Ge₂H₆), germanium tetrachloride (GeCl₄), dichlorogermane (GeH₂Cl₂), derivatives thereof, and combinations thereof. The silicon and/or germanium containing precursors may be used in combination with hydrogen chloride (HCl), chlorine gas (Cl₂), hydrogen bromide (HBr), and combinations thereof. The gas sources 840A, 840B may include one or more of the silicon and germanium containing precursors in one or both of the gas sources 840A, 840B.

The precursor materials enter the processing volume 818 through openings or a plurality of holes 858 (only one is shown in FIG. 7) in the perforated plate 854 in this excited state, which in one embodiment is a quartz material, having the holes 858 formed therethrough. The perforated plate 854 is transparent to IR energy, and may be made of a clear quartz material. In other embodiments, the perforated plate 854 may be any material that is transparent to IR energy and is resistant to process chemistry and other process chemistries. The energized precursor materials flow toward the processing volume 818 through the plurality of holes 858 in the perforated plate 854, and through a plurality of channels 852 (only one is shown in FIG. 7). A portion of the photons and non-thermal energy from the IR lamps 856 also passes through the holes 858, the perforated plate 854, and channels 852 facilitated by a reflective material and/or surface disposed on the interior surfaces of the gas distribution assembly 850, thereby illuminating the flow path of the precursor materials (shown as arrow 822 in FIG. 7). In this manner, the vibrational energy of the precursor materials may be maintained from the point of introduction to the processing volume 818 along the flow path.

FIG. 8 illustrates an exemplary vacuum processing system 900 that can be used to complete the processing sequence 100 illustrated in FIG. 1, according to implementations of the present disclosure. As shown in FIG. 8, a plurality of processing chambers 902a, 902b, 902c, 902d are coupled to a first transfer chamber 904. The processing chambers 902a-902d may be used to perform any substrate related processes, such as annealing, chemical vapor deposition, physical vapor deposition, epitaxial process, etching process, thermal oxidation or thermal nitridation process, degassing etc. In one implementation, the processing chamber 902a may be a film formation chamber, such as a vapor phase epitaxy deposition chamber, for example an Epi chamber available from Applied Materials, Santa Clara, Calif., that is capable of forming a crystalline silicon or silicon germanium. In another implementation, the processing chamber 902a may be an epitaxy deposition chamber such as the single-substrate processing reactor 600 described in connection with FIG. 5. In another implementation, the processing chamber 902a may be the process chamber 700 described in connection with FIG. 6. In another implementation, the processing chamber 902a may be the process chamber 800 described in connection with FIG. 7.

The processing chamber 902b may be a rapid thermal processing chamber (RTP). The processing chamber 902c is a plasma etching chamber or a plasma cleaning chamber. For example the processing chamber 902c may be the processing chamber 300 described in connection with FIG. 3. The processing chamber 902d may be a degassing chamber. The first transfer chamber 904 is also coupled to at least one transition station, for example a pair of pass-through stations 906, 908. The pass-through stations 906, 908 maintain vacuum conditions while allowing substrates to be transferred between the first transfer chamber 904 and a second transfer chamber 910. The first transfer chamber 904 has a robotic substrate handling mechanism (not shown) for transferring substrates between the pass-through stations 906, 908 and any of the processing chambers 902a-902d. The processing chambers 902a-902d are shown configured in a certain order in FIG. 8, but they may be configured in any desired order.

One end of the pass-through stations 906, 908 is coupled to the second transfer chamber 910. Therefore, the first transfer chamber 904 and the second transfer chamber 910 are separated and connected by the pass-through stations 906, 908. The second transfer chamber 910 is coupled to a first plasma-cleaning chamber 914, which can be a plasma chamber such as the processing chamber that is adapted to perform at least some of the processes found in FIG. 1 for removing oxides from a surface of a substrate. In one implementation, the first plasma-cleaning chamber 914 is a Siconi™ or Selectra™ chamber, which is available from Applied Materials, Santa Clara, Calif. In another implementation, the plasma cleaning chamber 914 may be the processing chamber 300 described in connection with FIG. 2.

In one implementation, the at least one transition station, for example one of the pass-through stations 906, 908, is configured to be a plasma-cleaning chamber. Alternatively, a plasma-cleaning chamber may be coupled to one of the pass-through stations 906, 908 for removing contaminants from the surface of the substrate. Thus, the processing system 900 may have a second plasma-cleaning chamber that is, or is connected to, one of the pass-through stations 906, 908. In one implementation shown in FIG. 8, the pass-through station 906 includes a second plasma-cleaning chamber 916. The second plasma-cleaning chamber 916 may be a version of the processing chamber 300 (FIG. 2) that is adapted to perform at least some of the processes found in box 104 for removing contaminants from the surface of the substrate. It should be noted that, although only one plasma-cleaning chamber 916 is shown coupled to a pass-through station, in this case the pass-through station 906, a plasma-cleaning chamber (e.g., a version of the processing chamber 300) may be coupled to both the pass-through stations 906 and 908.

The second transfer chamber 910 also has a robotic substrate handling mechanism (not shown) for transferring substrates between a set of load lock chamber 912 and the first plasma-cleaning chamber 914 or the second plasma-cleaning chamber 916. A factory interface 920 is connected to the second transfer chamber 910 by the load lock chambers 912. The factory interface 920 is coupled to one or more pods 930 on the opposite side of the load lock chambers 912. The pods 930 typically are front opening unified pods (FOUP) that are accessible from a clean room (not shown).

While two transfer chambers are shown, it is contemplated that any of the transfer chambers may be omitted. In one implementation where the second transfer chamber 910 is omitted, the second plasma-cleaning chamber 916 may be disposed within or coupled to the first transfer chamber 904 at the location currently shown as occupied by the pass-through stations 906 or 908. The first transfer chamber 904 may be coupled to one or more processing chambers capable of forming crystalline silicon or silicon germanium, such as an epitaxy chamber, for example a Centura™ Epi chamber available from Applied Materials, Inc., of Santa Clara, Calif. Alternatively, the first transfer chamber 904 may be omitted and the second plasma-cleaning chamber 916 may be disposed within or coupled to the pass-through station 906, which is coupled to the second transfer chamber 910. In such a case, the second transfer chamber 910 may be configured to be coupled to one or more processing chambers capable of forming crystalline silicon or silicon germanium.

In operation, substrates are carried from pods 930 to the vacuum processing system 900 in a transport cassette (not shown) that is placed within one of the load lock chambers 912. The robotic transport mechanism within the second transfer chamber 910 transports the substrates, one at a time, from the load lock chambers 912 to the first plasma-cleaning chamber 914 where the a cleaning process, e.g., processes found in FIG. 1, is performed to remove oxides from a surface of a substrate. Once the oxides have been removed from the substrate surface, the robotic transport mechanism disposed within the second transfer chamber 910 transfers the substrate from the first plasma-cleaning chamber 914 to the second plasma-cleaning chamber 916 where a reducing process, e.g., processes found in box 104, is performed to remove contaminants such as carbon or hydrocarbons from the substrate surface. It is contemplated that the steps here may also be performed in the reverse order, i.e., using the robotic transport mechanism to transfer the substrate from the second plasma-cleaning chamber 916 to the first plasma-cleaning chamber 914. In either case, the clean substrates are then transferred by the robotic transport mechanism disposed within the first transfer chamber 904 from the second plasma-cleaning chamber 916 (or the first plasma-cleaning chamber 914) to one or more processing chambers 902a-902d. The one or more processing chambers 902a-902d may include an epitaxy process chamber where a layer formation process, such as the epitaxial deposition described in box 106, is performed.

Upon completion of processing in the one or more processing chambers 902a-902d, the robotic transport mechanism disposed within the first transfer chamber 904 moves the substrate from either one of the processing chambers 902 to the pass-through station 908. The substrate is then removed from the pass-through station 908 by the robotic transport mechanism disposed within the second transfer chamber 910 and transferred to the other load lock chamber 912 through which it is withdrawn from the vacuum processing system 900.

Since the processes of all three boxes 103, 104 and 106 are performed within the same vacuum processing system 900, vacuum is not broken as the substrate is transferred among various chambers, which decreases the chance of contamination and improves the quality of the deposited epitaxial film. It should be understood that the movement of the substrates is described herein for illustration purposes. A controller (not shown) may be used to schedule the movement of the substrates through the vacuum processing system 900 in accordance with a desired sequencing program, which may vary depending upon the application.

Benefits of the present disclosure include an improved vacuum processing system integrating two different types of pre-clean process chambers with the epitaxial process chamber on the same vacuum processing system. The pre-clean process chambers may include a first plasma-cleaning process chamber and a second plasma-cleaning process chamber. Co-existence of two types of surface materials removal chamber on the same vacuum processing system allows substrates to remain in vacuum between surface preparation and epitaxial deposition, which reduces the time the substrates are exposed to ambient and eliminates the need to prepare the substrates on a separate processing chamber or system. This architecture also maximizes the number of process chambers on a vacuum system because the pass-through station between two transfer chambers also functions as a pre-clean process chamber, which also reduces overall handling time of the substrates.

An example of the processes of FIG. 1 can be performed in the processing chamber 300 of FIG. 2. Argon is routed through the remote plasma source 350, a first mixture of 25% HF in argon is routed through the inlet 356, and a second mixture of 25% NF₃ in argon is routed through the inlet 356 or a second inlet. The remote plasma is formed by applying 500 W of microwave or RF power to argon gas flowing at 2 sLm. The first mixture is flowed through the inlet 356 at 500 sccm and the second mixture is flowed through the second inlet at 500 sccm. The substrate is maintained at a temperature of 30 degrees Celsius by routing temperature control fluid through the channel 544 (shown in FIG. 4). The heating elements 520 may be powered to provide temperature control. The chamber is maintained at a pressure of 10 Torr, and the substrate is processed for a time suitable for converting all desired oxygen on the substrate surface into sublimable solid, for example 300 seconds. The substrate is then moved close to the gas distribution plate 326, which is heated to about 300 degrees Celsius to provide heating to the substrate surface. The substrate is maintained in proximity to the heat radiating from the gas distribution plate 326 for 1-5 minutes to sublime the solids formed on the substrate surface, leaving an oxygen-free surface. The substrate may then be optionally heat-treated under an inert atmosphere to remove any residual species from the oxide removal process, such as fluorine containing species. The heat treatment may include disposing the substrate in a thermal treatment chamber and energizing a thermal treatment apparatus in the chamber to heat the substrate to a temperature of about 300 degrees Celsius for about 1 minute.

An example of the process 104 of FIG. 1 can be performed in the processing chamber 300 of FIG. 2. Hydrogen gas is routed through the remote plasma source 350, which is powered at 500 W with microwave or RF power, at 2 sLm. The substrate is maintained at a temperature of about 500 degrees Celsius by heating the substrate support 314, and the process region 330 is maintained at a pressure of about 1 Torr. The substrate is processed at these conditions for a time suitable to remove all desired contaminant or foreign species and hydrogen terminate the surface of the substrate, for example about 1 minute. The substrate may then be optionally further heat treated, or annealed, under inert atmosphere by supplying an inert gas such as argon through the conduit 360 while discontinuing plasma power in the remote plasma source 350. The substrate can be maintained at an anneal temperature of 600 degrees Celsius. Alternately, the substrate can be moved to an anneal chamber, which may be coupled, for example, to the processing system 900 described in connection with FIG. 8, and annealed, or heat treated, at a higher temperature such as 800-1000 degrees Celsius, to remove any remaining surface defects to leave a uniformly clean and well-ordered surface crystal structure having minimal defects and impurities.

While the foregoing is directed to implementations of the present disclosure, other and further implementations of the disclosure may be devised without departing from the basic scope thereof.

1. A vacuum processing system, comprising:
a first transfer chamber coupled to at least one film formation chamber;
a second transfer chamber;
a plasma contaminant removal chamber coupled to the first or second transfer chamber, the plasma contaminant removal chamber having a heated substrate support operable to heat a substrate disposed thereon to a temperature of 650 degrees Celsius; and
a load lock chamber coupled to the second transfer chamber.

2. The vacuum processing system of claim 1, wherein the plasma contaminant removal chamber comprises a remote plasma source coupled to a lid of the chamber.

3. The vacuum processing system of claim 1, wherein the film formation chamber is an epitaxy chamber.

4. The vacuum processing system of claim 3, wherein the plasma contaminant removal chamber is a hydrogen plasma processing chamber.

5. The vacuum processing system of claim 4, further comprising an anneal chamber.

6. The vacuum processing system of claim 3, wherein the film formation chamber has the shape of a rectangular box in plan view.

7. A method of processing a substrate, comprising:
removing contaminants from the substrate by a process that includes exposing the substrate to hydrogen radicals at a temperature of at least about 400 degrees Celsius; and
forming a film on the substrate by an epitaxy process.

8. The method of claim 7, further comprising performing a thermal treatment process on the substrate by disposing the substrate in a thermal processing chamber, establishing a hydrogen atmosphere inside the thermal processing chamber, and heating the substrate to a temperature of 800 degrees Celsius to 1000 degrees Celsius.

9. The method of claim 8, wherein the thermal treatment process is performed in the same chamber as hydrogen radical exposure process.

10. The method of claim 7, wherein removing contaminants from the substrate comprises using a heated substrate support to heat the substrate to a temperature of 500 degrees Celsius to 650 degrees Celsius.

11. The method of claim 10, wherein exposing the substrate to hydrogen radicals comprises forming a plasma from a hydrogen containing gas and removing ions from the plasma using a magnetic field.

12. The method of claim 7, wherein exposing the substrate to hydrogen radicals comprises:
disposing the substrate in a processing chamber on a substrate support that has a heater;
heating the substrate to a temperature of at least 400 degrees Celsius;
forming a plasma from a hydrogen containing gas;
removing ions from the plasma using a magnetic field to form a hydrogen radical gas;
flowing the hydrogen radical gas into the processing chamber; and
exposing the substrate to the hydrogen radical gas.

13. The method of claim 12, further comprising annealing the substrate.

14. A vacuum processing apparatus, comprising:
a first transfer chamber coupled to at least one vapor phase epitaxy chamber;
a second transfer chamber coupled to the first transfer chamber by one or more pass-through stations;
a plasma contaminant removal chamber coupled to the first or second transfer chamber, the plasma contaminant removal chamber comprising:
a remote plasma source;
a magnetic ion filter; and
a substrate support operable to heat a substrate disposed thereon to a temperature between 400 degrees Celsius and 650 degrees Celsius; and
a load lock chamber coupled to the second transfer chamber.

15. The vacuum processing apparatus of claim 14, wherein the at least one vapor phase epitaxy chamber has the shape of a rectangular box in plan view.

16. The vacuum processing apparatus of claim 14, wherein the at least one vapor phase epitaxy chamber is an epitaxy chamber.

17. The vacuum processing apparatus of claim 14, wherein the remote plasma source is coupled to a lid of the chamber.

18. The vacuum processing apparatus of claim 14, wherein the at least one vapor phase epitaxy chamber comprises a plurality of elongated tube-type radiant heating elements.

19. The vacuum processing apparatus of claim 18, wherein the at least one vapor phase epitaxy chamber comprises a plurality of spot lamps.

20. The vacuum processing apparatus of claim 14, wherein the at least one vapor phase epitaxy chamber comprises a plurality of spot lamps.
